(19) United States
(12) Patent Application Publication
(10) Pub. No.: US 2016/0115595 A1
(43) Pub. Date: Apr. 28, 2016

(54) GAS SUPPLY APPARATUS

(71) Applicant: JUSUNG ENGINEERING CO., LTD., Gwangju-si, Gyeonggi-do (KR)

(72) Inventors: Chul Joo HWANG, Seongnam-si, Gyeonggi-do (KR); Ho Chul KANG, Gwangju-si, Gyeonggi-do (KR); Seung Yong YANG, Gwangju-si, Gyeonggi-do (KR); Myung Jin LEE, Gunpo-si, Gyeonggi-do (KR); Yong Hyun LEE, Seongnam-si, Gyeonggi-do (KR); Cheol Woo CHONG, Seoul (KR); Jae Wook CHOI, Seoul (KR)

(21) Appl. No.: 14/889,855

(22) PCT Filed: May 8, 2014
(86) PCT No.: PCT/KR2014/004095

§ 371 Date: Nov. 8, 2015

(30) Foreign Application Priority Data
May 8, 2013 (KR) 10-2013-0051652

(51) Int. Cl. C23C 16/455; C23C 14/22

(52) U.S. Cl. CPC C23C 16/45563; C23C 14/22

(57) ABSTRACT

The present invention relates to a gas supply device and, more specifically, to a gas supply device which can improve the flow of process gas within a process chamber and can increase a degree of uniformity of a deposition layer. The gas supply device, according to the present invention, comprises: a lead having a gas pipe connected thereto; a first plate for discharging, to a process chamber, gas introduced into the lead; a second plate provided so as to disperse gas flowing towards the bottom by being arranged between the lead and the first plate; a plurality of discharge holes on the first plate; and a plurality of discharge holes formed on the second plate, wherein a discharge hole formed at a corner section of the second plate is arranged in a different state from that of a discharge hole of a corner section formed at the same position on the first plate.

### TECHNICAL FIELD

The present invention relates to a gas supply apparatus, and more particularly to, a gas supply apparatus capable of improving process gas flow in a process chamber and enhancing uniformity of a deposited layer.

### BACKGROUND ART

In general, a liquid crystal display comprises a thin film transistor substrate including a thin film transistor and a pixel electrode which are provided at each pixel area defined by a gate wiring and a data wiring, a color filter substrate including a color filter layer and a common electrode, and a liquid crystal layer disposed between the two substrates. Lamps using LEDs may be used, according to use purposes thereof, in backlights, display apparatuses, luminaries, automobile indicator lights, headlamps, and the like.

In order to manufacture such a substrate, the following processes are repeatedly carried out several times: a thin film deposition process for depositing a raw material on a glass substrate, a photolithography process for exposing or shielding a region selected in the thin film using a photosensitive material, an etching process for patterning the thin film by removing the selected region in the thin film, and a washing process for removing foreign materials remaining on the substrate. Each of these processes is performed in a chamber having an optimum circumstance to the corresponding process.

FIG. 13 is a view schematically illustrating general constitution of PECVD equipment which is representative equipment for manufacturing a liquid crystal display. PECVD equipment includes a process chamber 10 which defines a predetermined reaction space, a susceptor 20 provided in the chamber 10, on which a substrate 30 is loaded, a first gas plate 41 formed with a plurality of spray holes 42, and a lid 43 disposed above the first gas plate 41 and connected with an external gas inlet 80.

A second gas plate 50 for diffusing process gas introduced through the gas inlet 80 to the first gas plate 41 is disposed between the lid 43 and the first gas plate 41. The second gas plate 50 is formed with a plurality of second holes 51.

The second gas plate 50 is formed to surround an area around an outlet port of the gas inlet 80, and is connected to a bottom surface of the lid 43.

The lid 43 is used as a plasma electrode for applying RF power to process gas. A RF power source 60 for supplying RF power is connected to the lid 43. An impedance matching box (I.M.B) 70 for matching impedance so as to apply maximum power is disposed between the lid 43 and the RF power source 60.

An electrode corresponding to the plasma electrode may be the grounded susceptor 20, and RF power may also be applied to the susceptor 20.

As shown in FIG. 14, the second gas plate 50 is formed with a plurality of second holes 51, which are arranged at an equidistant interval.

In detail, the second holes 51 are formed at the whole region e.g., a center portion, a region around the center portion and a region near the edge portions of the second gas plate 50, and an interval between the second holes 51 adjacent to each other is equal regardless of the position of the second holes 51.

However, if process gas is introduced into the process chamber 10 in the case in which the arrangement density of the second holes 51 on the second gas plate 50 is the same regardless of the region of the second gas plate 50 as described above and the second gas plate 50 has a smaller size than the first gas plate 41, a deposited layer deposited on the substrate is remarkably nonuniform in height.

In other words, a height of the deposited layer is gradually reduced from a center portion of the substrate 30 to edge portions of the substrate 30. The difference in height of the deposited layer between the center portion and the edge portions of the substrate 30 may be 10% or more.

Especially, such a phenomenon happens remarkably in a silicon oxide (SiOx) process rather than a silicon nitride (SiNx) process.

Such considerable non-uniformity of a deposited layer causes deterioration of properties, such as an aperture ratio, charge mobility, response speed and resolution, which are directly related to a quality of a liquid crystal display.

### DISCLOSURE

### Technical Problem

The present invention is directed to solve the problem which is described above. An object of the present invention is to provide a gas supply apparatus for producing a high-quality liquid crystal display by improving uniformity of a deposited layer on a substrate.

### Technical Solution

To achieve the object, the present invention supplies a gas supply apparatus comprises: a lid to which a gas inlet is connected;

a first plate to discharge gas introduced into the lid to a process chamber; a second plate disposed between the lid and the first plate to diffuse gas moving downward; a plurality of discharge holes formed at the first plate; and a plurality of discharge holes formed at the second plate. The discharge holes formed at corner portions of the second plate are arranged in a different pattern from the discharge holes formed at corner portions of the first plate corresponding to the corner portions of the second plate.

An interval between the discharge holes arranged at the corner portions may be different from an interval between the discharge holes arranged at portions other than the corner portions.

An interval between the discharge holes arranged at the corner portions may be greater than an interval between the discharge holes arranged at portions other than the corner portions.

An arrangement density of the discharge holes arranged at the corner portions may be different from an arrangement density of the discharge holes arranged at portions other than the corner portions.

An arrangement density of the discharge holes arranged at the corner portions may be lower than an arrangement density of the discharge holes arranged at portions other than the corner portions.

A diameter of the discharge holes arranged at the corner portions may be different from a diameter of the discharge holes arranged at portions other than the corner portions.

A diameter of the discharge holes arranged at the corner portions may be less than a diameter of the discharge holes arranged at portions other than the corner portions.

The number of the discharge holes of the first plate may be different from the number of the discharge holes of the second plate.

The number or arrangement pattern of the discharge holes formed at a center portion or edge portions of the first plate may be different from the number or arrangement pattern of the discharge holes formed at a center portion or edge portions of the second plate.

The second plate may include: a first region which corresponds to a center portion of the second plate; a second region which surrounds the first region; third regions which are near edge portions of the second plate around the second region; and fourth regions which correspond to the corner portions of the second plate.

An arrangement density of the discharge holes formed at the first region may be lower than an arrangement density of the discharge holes formed at the second region.

An arrangement density of the discharge holes formed at the first region may be a half of an arrangement density of the discharge holes formed at the second region.

An arrangement density of the discharge holes formed at the third regions may be lower than an arrangement density of the discharge holes formed at the second region.

An arrangement density of the discharge holes formed at the third regions may be a half of an arrangement density of the discharge holes formed at the second region.

An arrangement density of the discharge holes formed at the first region may correspond to an arrangement density of the discharge holes formed at the third regions.

A hole blocking ratio, which is defined by a ratio of an area of blocked discharge holes of the discharge holes formed at the corner portions to a whole area of the second plate, may be set to be in a predetermined range.

The corner portions may include plural unit regions which are separated from each other,

and the hole blocking ratio at each of the unit regions may be in the range from 0.5% to 3%.

The corner portions may have a right triangular shape,

and the corner portions may correspond to all corners of the second plate.

The corner portions may have an arc shape,

and the corner portions may correspond to all corners of the second plate.

The corner portions may have a step shape,

and the corner portions may correspond to all corners of the second plate.

A hole density ratio, which is defined by a ratio of an arrangement density of the discharge holes formed at the corner portions to an arrangement density of the discharge holes formed at the whole second plate, may be set to be in a predetermined range.

The corner portions may include plural unit regions which are separated from each other,

and the hole density ratio at each of the unit regions may be in the range from 38% to 48%.

The second plate may have a size corresponding to a size of the first plate,

and the second plate may be provided with a sealing member or shielding member along edges thereof, which is configured to contact an inner surface of the lid in order to prevent leakage of gas.

The second plate and the first plate may be apart from each other by a predetermined interval therebetween,

and the second plate and the lid may be apart from each other by a predetermined interval therebetween.

In accordance with another aspect of the present invention, a gas supply apparatus comprises: a lid to which a gas tube is connected;

a first plate formed with first discharge holes through which gas introduced into the lid is discharged to a process chamber;

and a second plate disposed between the lid and the first plate and formed with a plurality of second discharge holes through which gas moving toward the first plate is diffused.

A part of the plurality of second discharge holes formed at the second plate is

arranged in three or more divided regions, each of which includes two sides extending from each corner of the second plate and having a predetermined length.

An interval between the second discharge holes arranged at the divided regions may be different from an interval between the second discharge holes arranged at regions other than the divided regions.

An interval between the second discharge holes arranged at the divided regions may be greater than an interval between the second discharge holes arranged at regions other than the divided regions.

An arrangement density of the second discharge holes arranged at the divided regions may be different from an arrangement density of the second discharge holes arranged at regions other than the divided regions.

An arrangement density of the second discharge holes arranged at the divided regions may be lower than an arrangement density of the second discharge holes arranged at regions other than the divided regions.

A hole blocking ratio, which is defined by a ratio of an area of blocked second discharge holes of the second discharge holes formed at the divided regions to a whole area of the second plate, may be set to be in a predetermined range.

The divided regions may include plural unit regions which are separated from each other,

and the hole blocking ratio at each of the unit regions may be in the range from 0.5% to 3%.

A hole density ratio, which is defined by a ratio of an arrangement density of the second discharge holes formed at the divided regions to an arrangement density of the second discharge holes formed at the whole second plate, may be set to be in a predetermined range.

The divided regions may include plural unit regions which are separated from each other,

and the hole density ratio at each of the unit regions may be in the range from 38% to 48%.

### Advantageous Effects

According to the present invention, uniformity of the thickness of a deposited layer on the substrate can be secured.

Accordingly, an aperture ratio, charge mobility, response speed and resolution can be uniform all over the deposited layer. As a result, a quality of a liquid crystal display can be increased.

### DESCRIPTION OF DRAWINGS

FIG. 1 is a perspective view illustrating a gas supply apparatus according to the present invention.

FIG. 2 is a plan view of a first embodiment of a second plate mounted to the gas supply apparatus according to the present invention.

FIG. 3 is a plan view of a second embodiment of a second plate mounted to the gas supply apparatus according to the present invention.

FIG. 4 is a plan view of a third embodiment of a second plate mounted to the gas supply apparatus according to the present invention.

FIG. 5 is a sectional view of a deposited layer embodied by the gas supply apparatus depicted in FIG. 4.

FIG. 6 is a plan view of a fourth embodiment of a second plate mounted to the gas supply apparatus according to the present invention.

FIG. 7 is a plan view of a fifth embodiment of a second plate mounted to the gas supply apparatus according to the present invention.

FIG. 8 is a plan view of a sixth embodiment of a second plate mounted to the gas supply apparatus according to the present invention.

FIG. 9 is a sectional view of a deposited layer embodied by the gas supply apparatus depicted in FIG. 8.

FIG. 10 is a plan view of a seventh embodiment of a second plate mounted to the gas supply apparatus according to the present invention.

FIG. 11 is a plan view of an eighth embodiment of a second plate mounted to the gas supply apparatus according to the present invention.

FIG. 12 is an enlarged perspective view illustrating the gas supply apparatus according to the present invention.

FIG. 13 is a view illustrating a conventional gas supply apparatus.

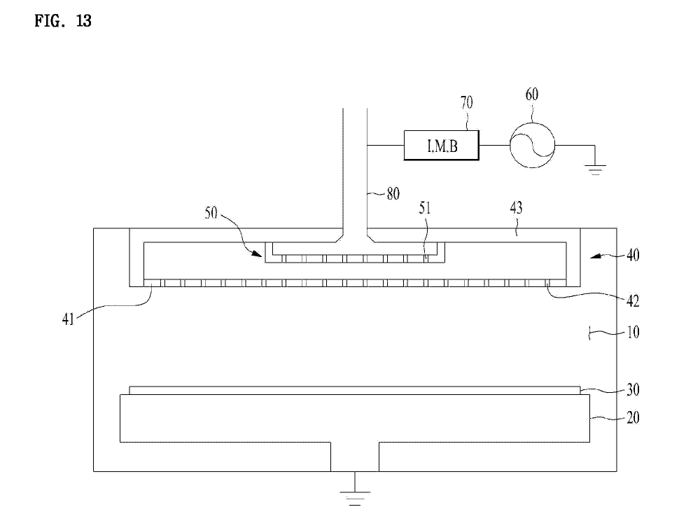

FIG. 14 is a plan view of a second plate of a conventional gas supply apparatus.

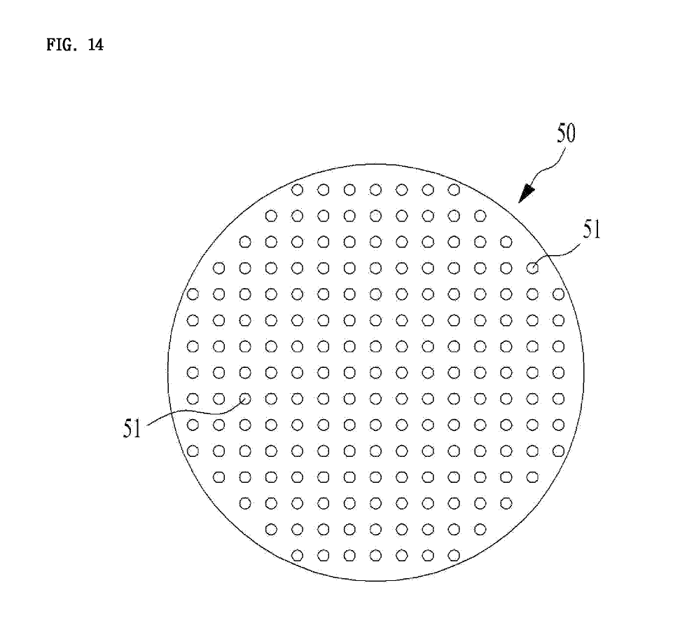

### BEST MODE

Now, preferred embodiments of the present invention will be described in detail with reference to the annexed drawings.

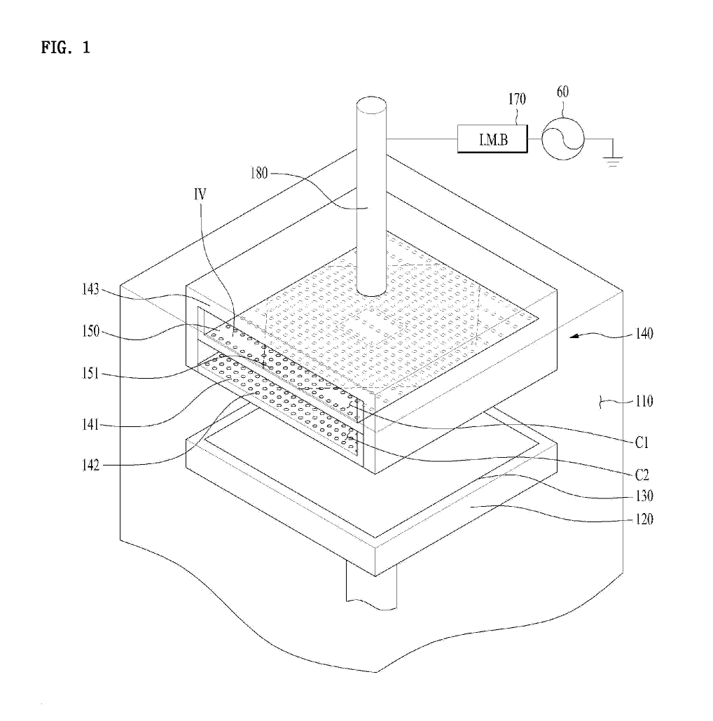

As shown in FIG. 1, a susceptor 120 on which a substrate 130 is loaded is provided at a lower portion of a process chamber 110 for performing a deposition process, and a gas supply apparatus 140 is provided at an upper portion of the process chamber 110.

The gas supply apparatus 140 includes a lid 143, and a first plate 141 and a second plate 150 which are disposed below the lid 143.

The first plate 141 becomes a first shower head, and the second plate 150 becomes a second shower head. The second plate 150 functions as a diffuser for diffusing process gas.

A space surrounded by the lid 143 and the first plate 141 is defined as a buffer chamber. Process gas which is temporarily accommodated in the buffer chamber is discharged into the process chamber 110 through the first plate 141.

The lid 143 is connected to a gas inlet tube 180. Process gas introduced through the gas inlet tube 180 is diffused in diverse directions by the second plate 150, and the diffused process gas moves to the process chamber 110 via the first plate 141.

The lid 143 functions as a plasma electrode for applying RF power to process gas. A RF power source 160 for supplying RF power is connected to the lid 143, and an impedance matching box (I.M.B) 170 for matching impedance so as to apply maximum power is disposed between the lid 143 and the RF power source 160.

An electrode corresponding to the plasma electrode may be the grounded susceptor 120, and RF power may also be applied to the susceptor 120.

The first plate 141 is formed with a plurality of first discharge holes 142, and the second plate 150 is also formed with a plurality of second discharge holes 151 through which process gas is discharged while being diffused.

The first plate 141 and the second plate 150 are spaced apart from each other by a predetermined interval in order to achieve smooth diffusion of process gas.

The interval between the first plate 141 and the second plate 150 is preferably from 5 mm to 7 mm, however, the interval may be changed according to circumstances.

Preferably, the second plate 150 has almost the same area or size as the first plate 141, or is formed similar to the first plate 141.

Accordingly, a process gas flow area on the second plate 150 and a process gas flow area on the first plate 141 can be almost equal or similar to each other. As a result, a deposited layer on the center portion and the edge portions of the substrate can be uniform in height.

A space between the second plate 150 and the lid 143 may be defined as a first buffer chamber C1, and a space between the second plate 150 and the first plate 141 may be defined as a second buffer chamber C2. In this case, an area of the first buffer chamber C1 and an area of the second buffer chamber C2 are almost equal or similar to each other.

Process gas is first introduced into the first buffer chamber C1 through the gas inlet tube 180 and then, flows through the second plate 150 while being diffused from the center portion to the edge portions of the first buffer chamber C1.

The process gas passing through the second plate 150 is introduced into the second buffer chamber C2 and is diffused and mixed in the second buffer chamber C2. Subsequently, the process gas passes through the first plate 141 and is introduced into the process chamber 110.

The second plate 150 has corner portions, which correspond to fourth regions IV which will be described later.

The second discharge holes 151 formed at the corner portions are arranged in a different pattern from the second discharge holes formed at regions other than the corner portions.

In particular, an arrangement density of the second discharge holes 151 on the corner portions is lower than that of the second discharge holes on the other regions. This means that an interval between the second discharge holes 151 on the corner portions is larger than that of the second discharge holes on the other regions.

Further, a diameter of the second discharge holes 151 formed at the corner portions may be smaller than that of the second discharge holes formed at the other regions.

Similar to the second plate 150, the first plate 141 is formed with first discharge holes 142 at portions which is corner portions thereof which corresponds to the corner portions of the second plate 150.

Preferably, the arrangement of the first discharge holes 142 formed at the corner portions of the first plate 141 is different from that of the second discharge holes 151 formed at the corner portions of the second plate 150.

On each of the corner portions, the arrangement density of the second discharge holes 151 may be lower than that of the first discharge holes 142, the interval between the second discharge holes 151 may be larger than that between the first discharge holes 142, or the diameter of the second discharge holes 151 may be smaller than that of the first discharge holes 142.

Meanwhile, the number or arrangement pattern of the first discharge holes 142 of the first plate 141 may be different from that of the second discharge holes 151 of the second plate 150.

The number or arrangement pattern of the first discharge holes 142 formed at the corner portions of the first plate 141 may be different from that of the second discharge holes 151 formed at the corner portions of the second plate 150. Further, difference in number or arrangement pattern between the first discharge holes 142 and the second discharge holes 151 may also be made at the edge portions or the center portions of the first and second plates 141 and 150.

It is illustrated in the drawings that front portions of the first buffer chamber C1 and the second buffer chamber C2 are opened, however, this is for making the constitution distinct in the drawings.

Originally, the first and second buffer chambers C1 and C2 should be sealed by the lid 143.

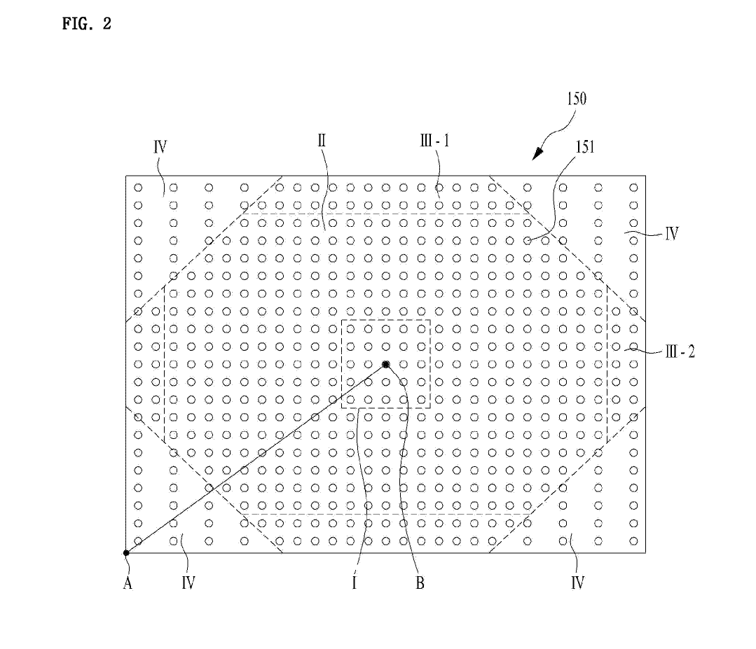

FIG. 2 is a view illustrating a first embodiment of the second plate 150 according to the present invention.

The second plate 150 is formed in a substantially rectangular shape, however, the shape of the second plate 150 is not limited thereto.

The second plate 150 may be divided into several regions.

In detail, the second plate 150 may be divided into a first region I which corresponds to the center portion and occupies a predetermined area, a second region II which surrounds the first region I and occupies the largest area, third regions III which are near the edge portions around the second region II, and fourth regions IV which correspond to the respective corner portions and have a substantially triangular shape adjacent to the third regions III and the second region II.

The third regions III may include two horizontal regions III-1 which extend horizontally and two vertical regions III-2 which extend vertically.

The area of the first region I may be set to be 12.5% of the whole area of the second plate 150, the horizontal regions III-1 of the third regions III may be set to be 6.5% of the whole area of the second plate 150, and the vertical regions III-2 of the third regions III may be set to be 5% of the whole area of the second plate 150.

The fourth regions IV have a substantially right triangular shape and form the respective four corner portions of the second plate 150.

The shape of the fourth regions IV is not limited to a right triangular shape. The fourth regions IV may have various shapes, each of which includes two sides extending from each corner of the second plate 150.

In other words, the fourth regions IV may have an arc shape or a step shape other than a triangular shape, which will be described later.

Therefore, the fourth regions IV can be defined as the corner portions.

The first embodiment has the following features: the arrangement density of the second discharge holes 151 on the fourth regions IV is lower than that of the second discharge holes 151 on the first to third regions.

This is for preventing deterioration of uniformity of a deposited layer, which may happen due to the relatively high density of process gas at the center portion and the edge portions.

If the arrangement density of the second discharge holes 151 on all the regions of the second plate 150 is the same, the thickness of a deposited layer on the center portion and the edge portions of the substrate become remarkably large, and the thickness of a deposited layer on the region therebetween becomes small.

Accordingly, uniformity of the thickness of a deposited layer can be secured by relatively lowering the arrangement density of the second discharge holes 151 at the edge portions of the second plate 150.

Preferably, the arrangement density of the second discharge holes 151 on the fourth regions IV is a half of the arrangement density on the first to third regions, or the interval between the second discharge holes 151 on the fourth regions IV is two times larger than the interval on the first to third regions.

For example, if the number of the second discharge holes 151 per predetermined unit area on the first to third regions is 10, the number of the second discharge holes 151 per predetermined unit area on the fourth regions IV is 5.

In the case in which the fourth regions IV are divided into at least three unit regions, more particularly, into four unit regions, if a ratio of the arrangement density of the second discharge holes 151 formed at one unit region of the fourth regions IV to the arrangement density of the second discharge holes 151 on the whole second plate 150 is set to be in the predetermined range, an error between the largest thickness and the smallest thickness of a deposited layer on the substrate can be reduced to 10% or less.

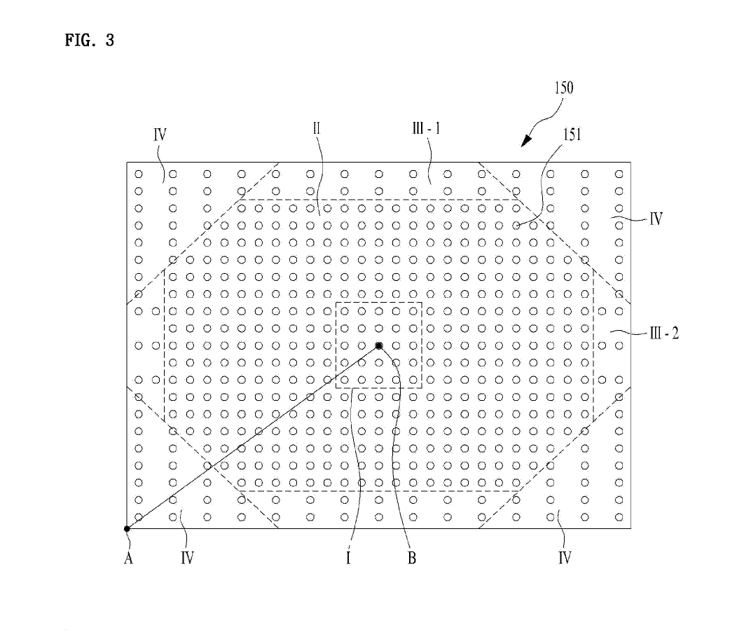

FIG. 3 is a view illustrating a second embodiment of the second plate 150 according to the present invention.

The second embodiment has the following features: the arrangement density of the second discharge holes 151 on the third regions III and the fourth regions IV of the second plate 150 is lower than that of the second discharge holes 151 on the first region I and the second region II.

Therefore, the arrangement density of the second discharge holes 151 is decreased from the center portion to the edge and corner portions of the second plate 150.

Similar to the first embodiment, this is for preventing deterioration of uniformity of a deposited layer, which may happen due to the relatively high density of process gas at the center portion and the edge portions.

If the arrangement density of the second discharge holes 151 on all the regions of the second plate 150 is the same, the thickness of a deposited layer on the center portion and the edge portions of the substrate become remarkably large, and the thickness of a deposited layer on the region therebetween becomes small.

Accordingly, uniformity of the thickness of a deposited layer can be secured by relatively lowering the arrangement density of the second discharge holes 151 at the edge portions of the second plate 150.

Preferably, the arrangement density of the second discharge holes 151 on the third and fourth regions is a half of the arrangement density on the first and second regions.

For example, if the number of the second discharge holes 151 per predetermined unit area on the first and second regions is 10, the number of the second discharge holes 151 per predetermined unit area on the third and fourth regions is 5.

Also in the second embodiment, in the case in which the fourth regions IV are divided into four unit regions, if a ratio of the arrangement density of the second discharge holes 151 formed at one unit region of the fourth regions IV to the arrangement density of the second discharge holes 151 on the whole second plate 150 is set to be in the predetermined range, an error between the largest thickness and the smallest thickness of a deposited layer on the substrate can be reduced to 10% or less.

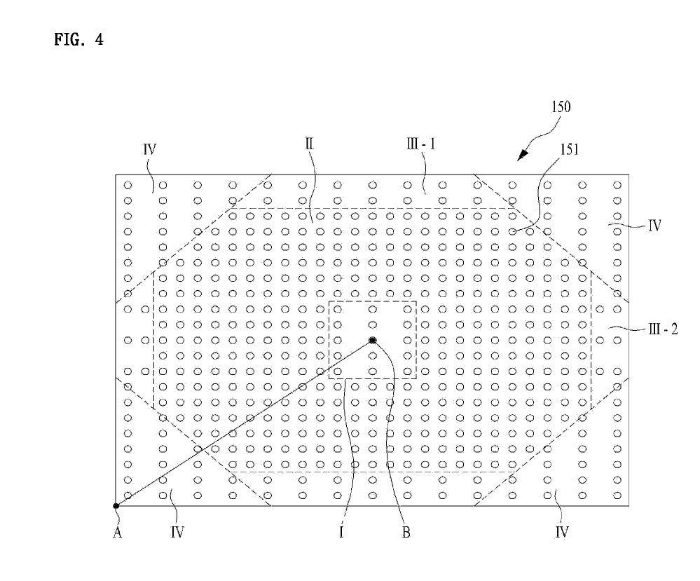

FIG. 4 is a view illustrating a third embodiment of the second plate 150 according to the present invention.

The third embodiment has the following features: the arrangement density of the second discharge holes 151 on the first region I, the third regions III and the fourth regions IV of the second plate 150 is lower than that of the second discharge holes 151 on the second region II.

Therefore, the arrangement density of the second discharge holes 151 is decreased from the center portion to the edge and corner portions of the second plate 150.

Similar to the first and second embodiments, this is for preventing deterioration of uniformity of a deposited layer, which may happen due to the relatively high density of process gas at the center portion and the edge portions.

If the arrangement density of the second discharge holes 151 on all the regions of the second plate 150 is the same, the thickness of a deposited layer on the center portion and the edge portions of the substrate become remarkably large, and the thickness of a deposited layer on the region therebetween becomes small.

Accordingly, uniformity of the thickness of a deposited layer can be secured by relatively lowering the arrangement density of the second discharge holes 151 at the edge portions of the second plate 150.

Preferably, the arrangement density of the second discharge holes 151 on the first, third and fourth regions is a half of the arrangement density on the second region.

For example, if the number of the second discharge holes 151 per predetermined unit area on the second region is 10, the number of the second discharge holes 151 per predetermined unit area on the first, third and fourth regions is 5.

In other words, the third embodiment has the following features: the arrangement density of the second discharge holes 151 is set to be low-high-low from the center portion to the edge portions.

Also in the third embodiment, in the case in which the fourth regions IV are divided into four unit regions, if a ratio of the arrangement density of the second discharge holes 151 formed at one unit region of the fourth regions IV to the arrangement density of the second discharge holes 151 on the whole second plate 150 is set to be in the predetermined range, an error between the largest thickness and the smallest thickness of a deposited layer on the substrate can be reduced to 10% or less.

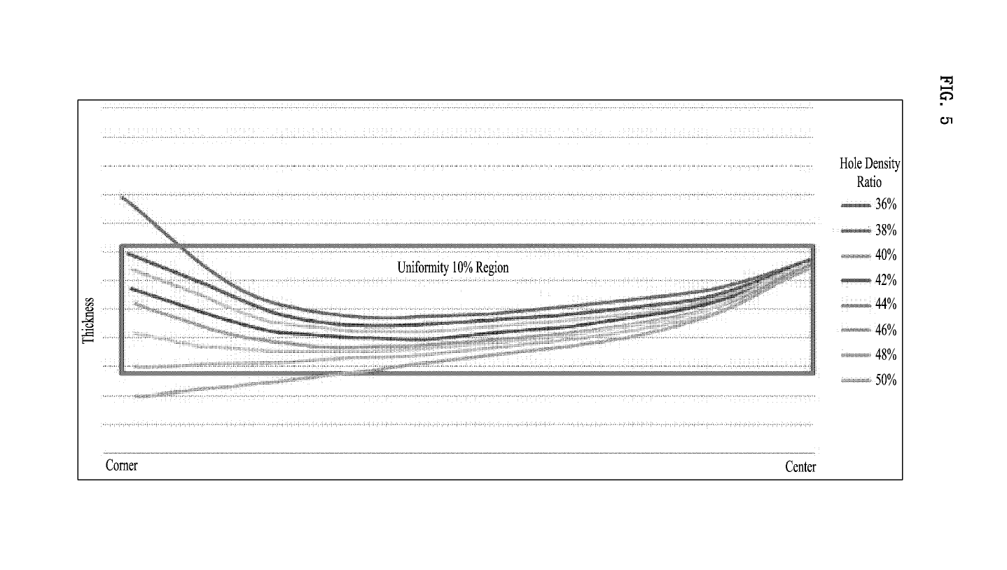

As shown in FIG. 5, if a ratio of the arrangement density of the second discharge holes 151 per predetermined unit area on one unit region of the fourth regions IV to the arrangement density of the second discharge holes 151 per predetermined unit area on the whole second plate 150 is kept in the range from 38% to 48%, an error between the largest thickness and the smallest thickness of a deposited layer on the substrate can be 10% or less.

In FIG. 5, the leftmost part refers to the thickness of a deposited layer on the substrate corresponding to one corner (point A in FIG. 4) of the second plate 150, and the rightmost part refers to the thickness of a deposited layer on the substrate corresponding to a center (point B in FIG. 4) of the second plate 150.

A red box in FIG. 5 refers to a region in which a thickness error of a deposited layer is 10% or less.

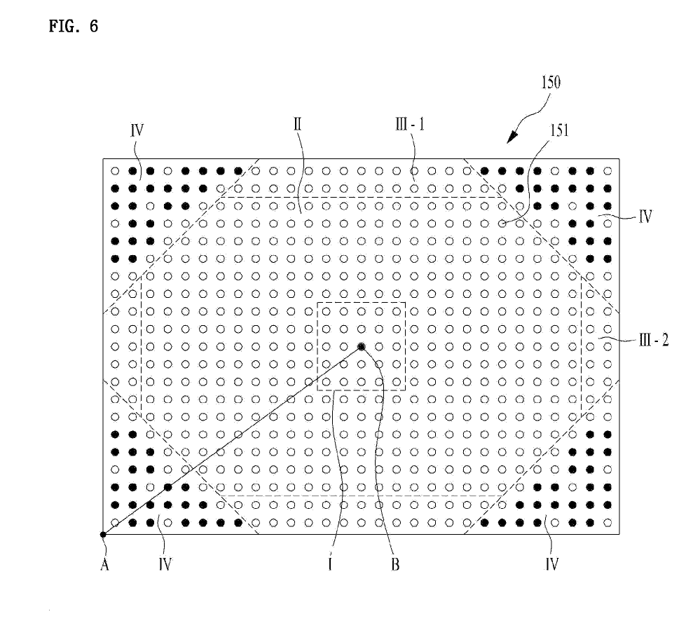

FIG. 6 is a view illustrating a fourth embodiment of the second plate 150 according to the present invention.

Also in the fourth embodiment, the second plate 150 is formed in a substantially rectangular shape, however, the shape of the second plate 150 is not limited thereto.

The second plate 150 may be divided into several regions.

In detail, the second plate 150 may be divided into a first region I which corresponds to the center portion and occupies a predetermined area, a second region II which surrounds the first region I and occupies the largest area, third regions III which are near the edge portions around the second region II, and fourth regions IV which correspond to the respective corner portions and have a substantially triangular shape adjacent to the third regions III and the second region II.

The third regions III may include two horizontal regions III-1 which extend horizontally and two vertical regions III-2 which extend vertically.

The area of the first region I may be set to be 12.5% of the whole area of the second plate 150, the horizontal regions III-1 of the third regions III may be set to be 6.5% of the whole area of the second plate 150, and the vertical regions III-2 of the third regions III may be set to be 5% of the whole area of the second plate 150.

The fourth regions IV have a substantially right triangular shape and form the respective four corner portions of the second plate 150.

The shape of the fourth regions IV is not limited to a right triangular shape. The fourth regions IV may have various shapes, each of which includes two sides extending from each corner of the second plate 150.

In other words, the fourth regions IV may have an arc shape or a step shape other than a triangular shape, which will be described later.

The fourth embodiment has the following features: a ratio of the area of blocked spots, illustrated by black points in FIG. 6, of the spots for second discharge hole formation in the fourth regions to the whole area of the second plate 150, i.e. area of blocked spots/whole area, determines the thickness of a deposited layer on the edge portions of the substrate.

In other words, in the case in which the fourth regions IV are divided into four unit regions, if some of the second discharge holes 151 formed at one unit region of the fourth regions IV are blocked and a ratio of the area of the blocked second discharge holes (illustrated by black points in FIG. 6) to the whole area of the second plate 150 is set to be in the predetermined range, an error between the largest thickness and the smallest thickness of a deposited layer on the substrate can be 10% or less.

Only in the fourth regions IV, some of the second discharge holes 151 are bored and the other second discharge holes 151 are blocked. All of the second discharge holes 151 in the first to third regions are bored.

Similar to the first to third embodiments, this is for preventing deterioration of uniformity of a deposited layer, which may happen due to the relatively high density of process gas at the center portion and the edge portions.

If the arrangement density of the second discharge holes 151 on all the regions of the second plate 150 is the same, the thickness of a deposited layer on the center portion and the edge portions of the substrate become remarkably large, and the thickness of a deposited layer on the region therebetween becomes small.

Accordingly, uniformity of the thickness of a deposited layer can be secured by relatively lowering the arrangement density of the second discharge holes 151 at the edge portions of the second plate 150.

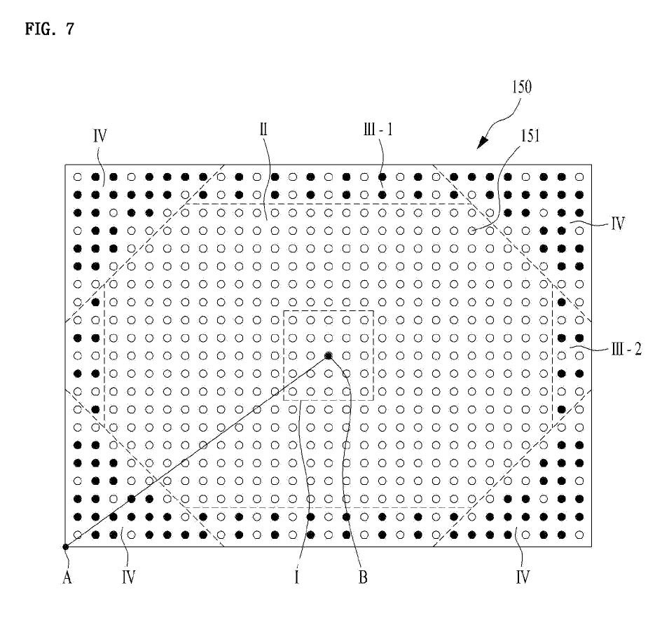

FIG. 7 is a view illustrating a fifth embodiment of the second plate 150 according to the present invention.

In the fifth embodiment, while some of the second discharge holes 151 in the fourth regions IV and the third regions III are blocked, all of the second discharge holes 151 in the first region I and the second region II are bored.

Therefore, the arrangement density of the second discharge holes 151 in the fourth regions IV and the third regions III is lower than the arrangement density in the first region I and the second region II.

Similar to the first to fourth embodiments, this is for preventing deterioration of uniformity of a deposited layer, which may happen due to the relatively high density of process gas at the center portion and the edge portions.

If the arrangement density of the second discharge holes 151 on all the regions of the second plate 150 is the same, the thickness of a deposited layer on the center portion and the edge portions of the substrate become remarkably large, and the thickness of a deposited layer on the region therebetween becomes small.

Accordingly, uniformity of the thickness of a deposited layer can be secured by relatively lowering the arrangement density of the second discharge holes 151 at the edge portions of the second plate 150.

Similar to the first to fourth embodiments, this is for preventing deterioration of uniformity of a deposited layer, which may happen due to the relatively high density of process gas at the center portion and the edge portions.

If the arrangement density of the second discharge holes 151 on all the regions of the second plate 150 is the same, the thickness of a deposited layer on the center portion and the edge portions of the substrate become remarkably large, and the thickness of a deposited layer on the region therebetween becomes small.

Accordingly, uniformity of the thickness of a deposited layer can be secured by relatively lowering the arrangement density of the second discharge holes 151 at the edge portions of the second plate 150.

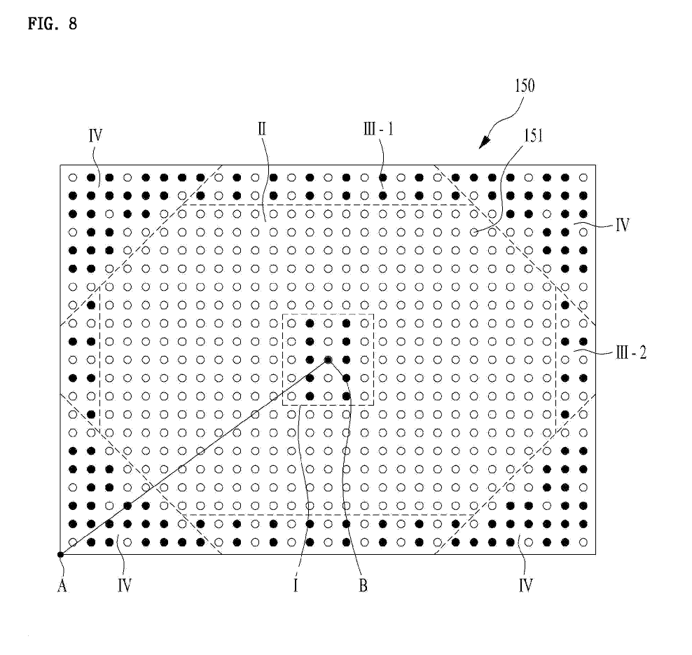

FIG. 8 is a view illustrating a sixth embodiment of the second plate 150 according to the present invention.

In the sixth embodiment, while some of the second discharge holes 151 in the fourth regions IV, the third regions III and the first region I are blocked, all of the second discharge holes 151 in the second region II are bored.

Therefore, the arrangement density of the second discharge holes 151 in the fourth regions IV, the third regions III and the first region I is lower than the arrangement density in the second region II.

Similar to the first to fifth embodiments, this is for preventing deterioration of uniformity of a deposited layer, which may happen due to the relatively high density of process gas at the center portion and the edge portions.

If the arrangement density of the second discharge holes 151 on all the regions of the second plate 150 is the same, the thickness of a deposited layer on the center portion and the edge portions of the substrate become remarkably large, and the thickness of a deposited layer on the region therebetween becomes small.

Accordingly, uniformity of the thickness of a deposited layer can be secured by relatively lowering the arrangement density of the second discharge holes 151 at the edge portions and the center portion of the second plate 150.

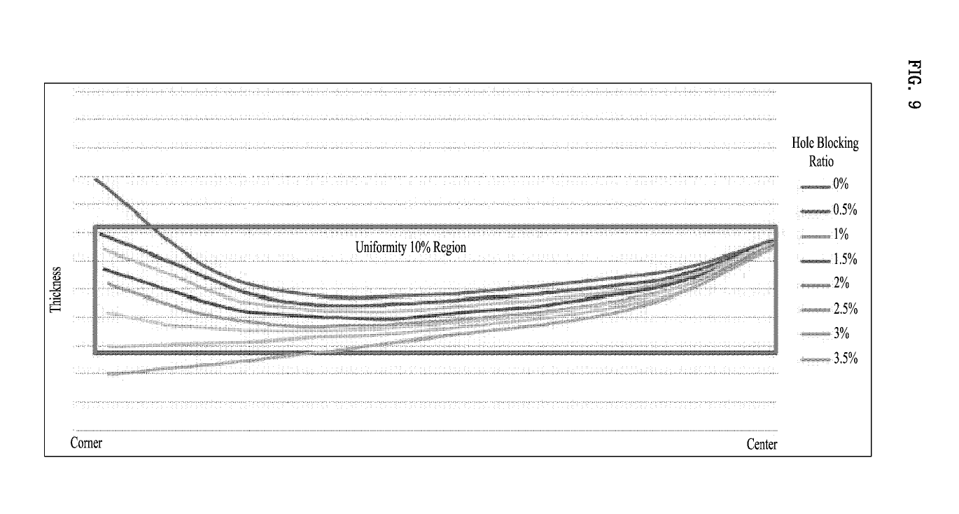

As shown in FIG. 9, if a ratio of the area of the blocked second discharge holes 151 at one unit region of the fourth regions IV to the whole area of the second plate 150 is set to be in the range from 0.5% to 3%, an error between the largest thickness and the smallest thickness of a deposited layer on the substrate can be 10% or less.

In FIG. 9, the leftmost part refers to the thickness of a deposited layer on the substrate corresponding to one corner (point A in FIG. 8) of the second plate 150, and the rightmost part refers to the thickness of a deposited layer on the substrate corresponding to a center (point B in FIG. 8) of the second plate 150.

A red box in FIG. 9 refers to a region in which a thickness error of a deposited layer is 10% or less.

Since the fourth regions IV are divided into four unit regions, if a ratio of the area of the blocked second discharge holes 151 at one unit region of the fourth regions IV to the whole area of the second plate 150 is set to be 0.5% to 3%, a ratio of the area of the blocked second discharge holes 151 at the whole fourth regions IV to the whole area of the second plate 150 becomes 2% to 12%.

Here, the expression “second discharge holes 151 are blocked” preferably means that the second discharge holes 151 are not originally formed (i.e., not bored) at the spots for second discharge hole formation, rather than that the already-formed second discharge holes are blocked.

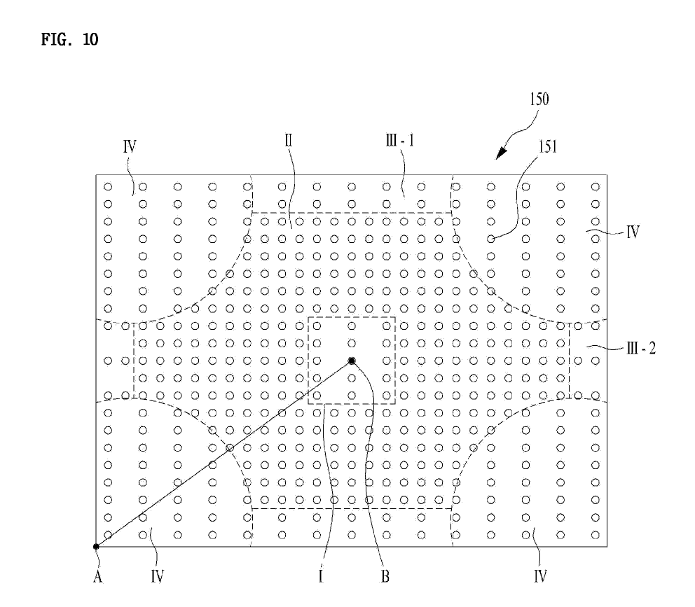

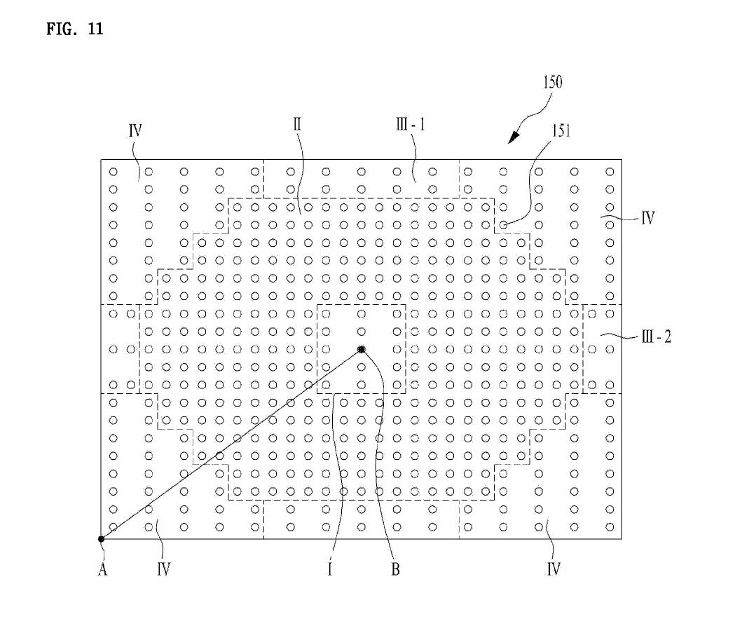

FIG. 10 is a view illustrating a seventh embodiment of the second plate 150 according to the present invention, in which the fourth regions IV are formed in an arc shape, not a right triangular shape. FIG. 11 is a view illustrating an eighth embodiment of the second plate 150 according to the present invention, in which the fourth regions IV are formed in a step shape, not a right triangular shape or an arc shape.

Since all the features of the seventh and eighth embodiments, except for difference in shape of the fourth regions IV, are the same as those of the first through sixth embodiments, detailed explanation thereof will be omitted to avoid repetition.

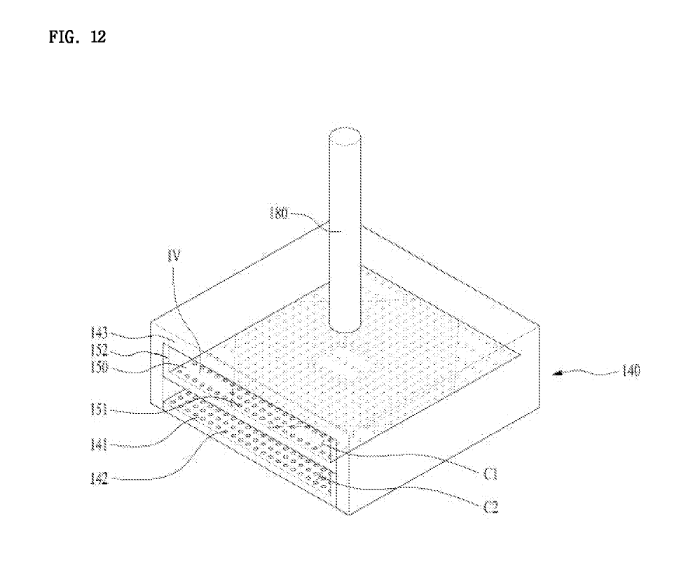

As shown in FIG. 12, the second plate 150 and the first plate 141 should be apart from each other by a predetermined interval therebetween, and the second plate 150 and the lid 143 should also be apart from each other by a predetermined interval therebetween.

Preferably, the gas supply apparatus 140 may further include a spacer (not shown) for holding these intervals.

Preferably, a shielding member or sealing member 152 is provided along edges of the second plate 150 in order to prevent process gas introduced toward the second plate 150 from leaking in other directions without passing through the second discharge holes 151.

The shielding member or sealing member 152 is configured to contact an inner surface of the lid 143, thereby preventing process gas from leaking through the contact portion.

Hereinafter, operation of the gas supply apparatus according to the present invention will be described with reference to the annexed drawings.

As shown in FIG. 1, in order to perform a deposition process, process gas is introduced through the gas inlet tube 180, and power is applied to the RF power source 160.

The process gas introduced through the gas inlet tube 180 is temporarily stored in the first buffer chamber C1. Since the area of the first buffer chamber C1 is much greater than the area of the outlet port of the gas inlet tube 180, the process gas is diffused rapidly.

The process gas diffused in the first buffer chamber C1 flows over the second plate 150 and moves into the second buffer chamber C2 through the second discharge holes 151 of the second plate 150.

The second discharge holes 151 are not arranged with a constant interval therebetween on the whole surface of the second plate 150. In other words, the arrangement density of the second discharge holes 151 is different locally.

As shown in FIG. 2 or 4, the arrangement density of the second discharge holes 151 in the center portion (first region), the edge portions (third regions) and the corner portions (fourth regions) of the second plate 150 is lower than the arrangement density of the second discharge holes 151 in the other portion (second region).

Because the center portion of the second plate 150 is near the outlet port of the gas inlet tube 180, process gas is intended to concentratedly pass through the center portion. Therefore, if the arrangement density of the second discharge holes 151 in the center portion (first region) of the second plate 150 is the same as the arrangement density in the second region, the amount of gas passing through the center portion of the second plate 150 becomes large, and thus the amount of gas passing through the center portion of the first plate 141 also becomes large.

Therefore, the thickness of a deposited layer formed on the center portion of the substrate 130 may be much greater than that of a deposited layer formed on other portions of the substrate 130.

In order to prevent such unbalanced increase in thickness of a deposited layer on the center portion of the substrate 130, the arrangement density of the second discharge holes 151 in the center portion (first region) of the second plate 150 should be necessarily lower than the arrangement density in the other portion (second region).

On the other hand, the diffused process gas may be concentrated on the edge portions of the second plate 150 by inertia due to high diffusion speed.

Therefore, if the arrangement density of the second discharge holes 151 in the edge portions of the second plate 150 is the same as the arrangement density in the second region, the amount of gas passing through the edge portions of the second plate 150 becomes large, and thus the amount of gas passing through the edge portions of the first plate 141 also becomes large.

Therefore, the thickness of a deposited layer formed on the edge portions of the substrate 130 may be much greater than that of a deposited layer formed on other portions of the substrate 130.

In order to prevent such unbalanced increase in thickness of a deposited layer on the edge portions of the substrate 130, the arrangement density of the second discharge holes 151 in the edge portions (third and fourth regions) of the second plate 150 should be necessarily lower than the arrangement density in the other portion (second region).

As described above, by setting the arrangement density of the second discharge holes 151 in the center portion and the edge portions of the second plate 150 to be lower than the arrangement density in the other portion, difference (uniformity) between the largest thickness and the smallest thickness of a deposited layer on the substrate can be reduced to 10% or less as illustrated in FIG. 5 or FIG. 9.

If uniformity of 10% or less is secured, an aperture ratio, charge mobility, response speed and resolution can be uniform all over the deposited layer, and a quality of a liquid crystal display can be increased.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A gas supply apparatus comprising:
a lid to which a gas tube is connected;
a first plate to discharge gas introduced into the lid to a process chamber;
a second plate disposed between the lid and the first plate to diffuse gas moving downward;
a plurality of discharge holes formed at the first plate; and
a plurality of discharge holes formed at the second plate, wherein the discharge holes formed at corner portions of the second plate are arranged in a different pattern from the discharge holes formed at corner portions of the first plate corresponding to the corner portions of the second plate.

2. The gas supply apparatus according to claim 1, wherein an interval between the discharge holes arranged at the corner portions is different from an interval between the discharge holes arranged at portions other than the corner portions.

3. The gas supply apparatus according to claim 2, wherein an interval between the discharge holes arranged at the corner portions is greater than an interval between the discharge holes arranged at portions other than the corner portions.

4. The gas supply apparatus according to claim 1, wherein an arrangement density of the discharge holes arranged at the corner portions is different from an arrangement density of the discharge holes arranged at portions other than the corner portions.

5. The gas supply apparatus according to claim 4, wherein an arrangement density of the discharge holes arranged at the corner portions is lower than an arrangement density of the discharge holes arranged at portions other than the corner portions.

6-32. (canceled)

33. The gas supply apparatus according to claim 1, wherein the number or arrangement pattern of the discharge holes formed at a center portion or edge portions of the first plate is different from the number or arrangement pattern of the discharge holes formed at a center portion or edge portions of the second plate.

34. The gas supply apparatus according to claim 1, wherein the second plate includes:
a first region which corresponds to a center portion of the second plate;
a second region which surrounds the first region;
third regions which are near edge portions of the second plate around the second region; and
fourth regions which correspond to the corner portions of the second plate.

35. The gas supply apparatus according to claim 34, wherein an arrangement density of the discharge holes formed at the first region is lower than an arrangement density of the discharge holes formed at the second region, and
an arrangement density of the discharge holes formed at the first region is a half of an arrangement density of the discharge holes formed at the second region.

36. The gas supply apparatus according to claim 34, wherein an arrangement density of the discharge holes formed at the third regions is lower than an arrangement density of the discharge holes formed at the second region.

37. The gas supply apparatus according to claim 36, wherein an arrangement density of the discharge holes formed at the third regions is a half of an arrangement density of the discharge holes formed at the second region.

38. The gas supply apparatus according to claim 37, wherein an arrangement density of the discharge holes formed at the first region corresponds to an arrangement density of the discharge holes formed at the third regions.

39. The gas supply apparatus according to claim 1, wherein a hole density ratio, which is defined by a ratio of an arrangement density of the discharge holes formed at the corner portions to an arrangement density of the discharge holes formed at the whole second plate, is set to be in a predetermined range.

40. The gas supply apparatus according to claim 39, wherein the corner portions include plural unit regions which are separated from each other, and
the hole density ratio at each of the unit regions is in the range from 38% to 48%.

41. The gas supply apparatus according to claim 1, wherein the second plate and the first plate are apart from each other by a predetermined interval therebetween, and the second plate and the lid are apart from each other by a predetermined interval therebetween.

42. A gas supply apparatus comprising:
a lid to which a gas tube is connected;
a first plate formed with first discharge holes through which gas introduced into the lid is discharged to a process chamber; and
a second plate disposed between the lid and the first plate and formed with a plurality of second discharge holes through which gas moving toward the first plate is diffused, wherein a part of the plurality of second discharge holes formed at the second plate is arranged in three or more divided regions, each of which includes two sides extending from each corner of the second plate and having a predetermined length.

43. The gas supply apparatus according to claim 42, wherein an interval between the second discharge holes arranged at the divided regions is different from an interval between the second discharge holes arranged at regions other than the divided regions.

44. The gas supply apparatus according to claim 43, wherein an interval between the second discharge holes arranged at the divided regions is greater than an interval between the second discharge holes arranged at regions other than the divided regions.

45. The gas supply apparatus according to claim 42, wherein an arrangement density of the second discharge holes arranged at the divided regions is different from an arrangement density of the second discharge holes arranged at regions other than the divided regions.

46. The gas supply apparatus according to claim 42, wherein a hole density ratio, which is defined by a ratio of an arrangement density of the second discharge holes formed at the divided regions to an arrangement density of the second discharge holes formed at the whole second plate, is set to be in a predetermined range.

47. The gas supply apparatus according to claim 46, wherein the divided regions include plural unit regions which are separated from each other, and
the hole density ratio at each of the unit regions is in the range from 38% to 48%.
